(19) United States
(12) Patent Application Publication
(10) Pub. No.: US 2022/0190043 A1
(43) Pub. Date: Jun. 16, 2022

(54) DISPLAY DEVICE, MANUFACTURING METHOD THEREOF, AND TERMINAL DEVICE

(71) Applicant: WUHAN CHINA STAR OPTOELECTRONICS SEMICONDUCTOR DISPLAY TECHNOLOGY CO., LTD., Wuhan (CN)

(72) Inventor: Xiaoming Ge, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/053,776

(22) PCT Filed: Jun. 22, 2020
(86) PCT No.: PCT/CN2020/097463

§ 371 Date: Nov. 8, 2020

(30) Foreign Application Priority Data
Apr. 26, 2020 (CN) 202010339863.7

(51) Int. Cl. H01L 27/32; G06F 3/041; H01L 51/52; H01L 51/56

(52) U.S. Cl. CPC H01L 27/323; G06F 3/041; H01L 27/3234; G06F 2203/04103; H01L 51/5284; H01L 51/56; H01L 51/5281

(57) ABSTRACT

This application provides a display device, a manufacturing method thereof, and a terminal device. The display device includes a display area and an electronic component installation area. The display device includes a backplate, a display panel, a polarizing functional layer, a touch functional layer, and a cover plate, which are stacked, wherein a light transmittance of the touch functional layer is greater than a threshold value. A hole is formed in the electronic component installation area of the display device, and the hole penetrates the backplate, the display panel, and the polarizing functional layer. The touch functional layer does not require a wiring bypass process, and the manufacturing process is simple.

### FIELD OF INVENTION

The present application relates to the field of display technology, and in particular, to a display device, a manufacturing method thereof, and a terminal device.

### BACKGROUND OF INVENTION

With advances in full-screen technology, the technique of placing electronic components, such as cameras, under a display screen has become a trend, and correspondingly, display screens need to be drilled with holes. However, in current display devices, a touch layer in the hole drilling area adopts direct on-cell touch (DOT) technology, and the touch layer in this area is also requires drilling. In order to achieve normal operation of the touch layer, wiring at the drilling area needs to bypass the area through a through-hole, but the manufacturing process is relatively complicated. Therefore, the current display device has a technical problem in that the manufacturing process of the touch layer in the drilling area is relatively complicated, and needs to be improved.

### Technical Problem

The present application provides a display device, a manufacturing method thereof, and a terminal device, so as to alleviate the technical problem of the current display device that the manufacturing process of the touch layer in the drilling area is relatively complicated.

### SUMMARY OF INVENTION

In order to solve the above problems, the technical solutions provided by this application are as follows:

The present application provides a display device including a display area and an electronic component installation area corresponding to an installation position of an electronic component. The display device includes: a backplate; a display panel disposed on a side of the backplate; a polarizing functional layer disposed on a side of the display panel away from the backplate; a touch functional layer disposed on a side of the polarizing functional layer away from the display panel, wherein light transmittance of the touch functional layer is greater than a threshold value; a cover plate disposed on a side of the touch functional layer away from the polarizing functional layer; wherein an opening is formed in the electronic component installation area of the display device, and the opening penetrates the backplate, the display panel, and the polarizing functional layer.

In the display device of the present application, material of the touch functional layer includes silver nanowires.

In the display device of the present application, the touch functional layer is bonded to the cover plate through a first adhesive layer and bonded to the polarizing functional layer through a second adhesive layer, and the opening penetrates the second adhesive layer.

In the display device of the present application, the first adhesive layer and the second adhesive layer are made of optical adhesives.

In the display device of the present application, a light-shielding layer is further disposed between the cover plate and the polarizing functional layer in the electronic component installation area, and the light-shielding layer is a ring structure concentric with the opening.

In the display device of the present application, an inner diameter of the light-shielding layer is less than or equal to an inner diameter of the opening.

In the display device of the present application, the light-shielding layer is formed at least one position between the cover plate and the touch functional layer or the touch functional layer and the polarizing functional layer.

In the display device of the present application, material of the light-shielding layer is ink.

The present application also provides a manufacturing method of a display device, including:

providing a backplate, a display panel, a polarizing functional layer, a touch functional layer, and a cover plate, wherein light transmittance of the touch functional layer is greater than a threshold value;

bonding the backplate, the display panel, the polarizing functional layer, the touch functional layer, and the cover plate together; and

forming an opening in the electronic component installation area, and allowing the opening penetrates the backplate, the display panel, and the polarizing functional layer.

In the manufacturing method of the display device of the present application, the steps of forming the opening in the electronic component installation area, and allowing the opening to penetrate the backplate, the display panel, and the polarizing functional layer includes:

using an ultraviolet picosecond laser to cut the backplate, the display panel, and the polarizing functional layer to form the opening, on a side of the backplate away from the display panel.

In the manufacturing method of the display device of the present application, the steps of providing the backplate, the display panel, the polarizing functional layer, the touch functional layer, and the cover plate, wherein light transmittance of the touch functional layer is greater than a threshold value includes: providing a touch functional layer including material of silver nanowires.

In the manufacturing method of the display device of the present application, the steps of bonding the backplate, the display panel, the polarizing functional layer, the touch functional layer, and the cover plate together includes steps of: bonding the touch functional layer to the cover plate through a first adhesive layer, and bonding the touch functional layer to the polarizing functional layer through a second adhesive layer.

In the manufacturing method of the display device of the present application, the steps of bonding the touch functional layer to the cover plate through the first adhesive layer, and bonding the touch functional layer to the polarizing functional layer through the second adhesive layer includes: bonding the touch functional layer to the cover plate through the first adhesive layer made of an optical adhesive and bonding the touch functional layer to the polarizing functional layer through the second adhesive layer made of the optical adhesive.

In the manufacturing method of the display device of the present application, before the step of forming the opening in the electronic component installation area further includes steps of:

providing a light-shielding layer between the cover plate and the polarizing functional layer in the electronic component installation area, and the light-shielding layer being a ring structure concentric with the opening.

In the manufacturing method of the display device of the present application, the steps of providing the light-shielding layer between the cover plate and the polarizing functional layer in the electronic component installation area, and the light-shielding layer being the ring structure concentric with the opening includes: providing the light-shielding layer, and an inner diameter of the light-shielding layer less than or equal to an inner diameter of the opening.

In the manufacturing method of the display device of the present application, the step of providing the light-shielding layer between the cover plate and the polarizing functional layer in the electronic component installation area includes: forming the light-shielding layer at least one position between the cover plate and the touch functional layer or the touch functional layer and the polarizing functional layer.

In the manufacturing method of the display device of the present application, the step of providing the light-shielding layer between the cover plate and the polarizing functional layer in the electronic component installation area includes: forming the light-shielding layer made of material of ink.

The present application also provides a terminal device, including a display device and a housing, wherein the display device includes a display area and an electronic component installation area corresponding to an installation position of an electronic component, and the display device includes: a backplate; a display panel disposed on a side of the backplate; a polarizing functional layer disposed on a side of the display panel away from the backplate; a touch functional layer disposed on a side of the polarizing functional layer away from the display panel, and light transmittance of the touch functional layer is greater than a threshold value; a cover plate disposed on a side of the touch functional layer away from the polarizing functional layer; wherein an opening is formed in the electronic component installation area of the display device, and the opening penetrates the backplate, the display panel, and the polarizing functional layer.

In the terminal device of the present application, material of the touch functional layer includes silver nanowires.

In the terminal device of the present application, the touch functional layer is bonded to the cover plate through a first adhesive layer and bonded to the polarizing functional layer through a second adhesive layer, and the opening penetrates the second adhesive layer.

### Beneficial Effect

The beneficial effects of this application: The present application provides a display device, a manufacturing method thereof, and a terminal device. The display device includes a display area and an electronic component installation area corresponding to an installation position of an electronic component. The display device includes a backplate, a display panel, a polarizing functional layer, a touch functional layer, and a cover plate. The display panel is disposed on a side of the backplate. The polarizing functional layer is disposed on a side of the display panel away from the backplate. The touch functional layer is disposed on a side of the polarizing functional layer away from the display panel, wherein light transmittance of the touch functional layer is greater than a threshold value. The cover plate is disposed on a side of the touch functional layer away from the polarizing functional layer, wherein a hole is formed in the electronic component installation area of the display device, and the hole penetrates the backplate, the display panel, and the polarizing functional layer. The light transmittance of the touch functional layer of the present application is greater than a threshold value, so the light transmittance of electronic components can be ensured. The hole in the electronic component installation area does not need to penetrate the touch functional layer, and can also achieve the purpose of touch control and placing electronic components. Therefore, no wiring bypass process is needed in the touch functional layer, the manufacturing process is simple, and the cost is reduced.

### DESCRIPTION OF DRAWINGS

In order to more clearly explain the embodiments or the technical solutions in the prior art, the following will briefly introduce the drawings in the embodiments or the description of the prior art. Obviously, the drawings in the description are only some embodiments of the application. For those of ordinary skill in the art, other drawings can be obtained based on these drawings without doing any creative work.

FIG. 1 is a structural schematic diagram of a film layer of a display device provided by an embodiment of the present application.

FIG. 2 is a structural schematic plan view of a display device provided by an embodiment of the present application.

FIG. 3 is a method schematic flowchart for of a method of manufacturing a display device provided by an embodiment of the present application.

FIG. 4 is a schematic diagram showing a third step in the method of manufacturing a display device provided by an embodiment of the present application.

### DETAILED DESCRIPTION OF PREFERRED EMBODIMENTS

The descriptions of the following embodiments refer to the drawings to illustrate specific embodiments that can be implemented in the present application. The terminology mentioned in this application, such as “upper”, “lower”, “front”, “back”, “left”, “right”, “inner”, “outer”, “side”, etc., refers only to the directions of the drawings. Therefore, the directional terminology is to illustrate and understand this application, not to limit this application. In the drawings, units with similar structures are indicated by the same reference numerals.

The present application provides a display device, a manufacturing method thereof, and a terminal device, so as to alleviate the technical problem that the manufacturing process of the touch layer in the drilling area of the current display device is relatively complicated.

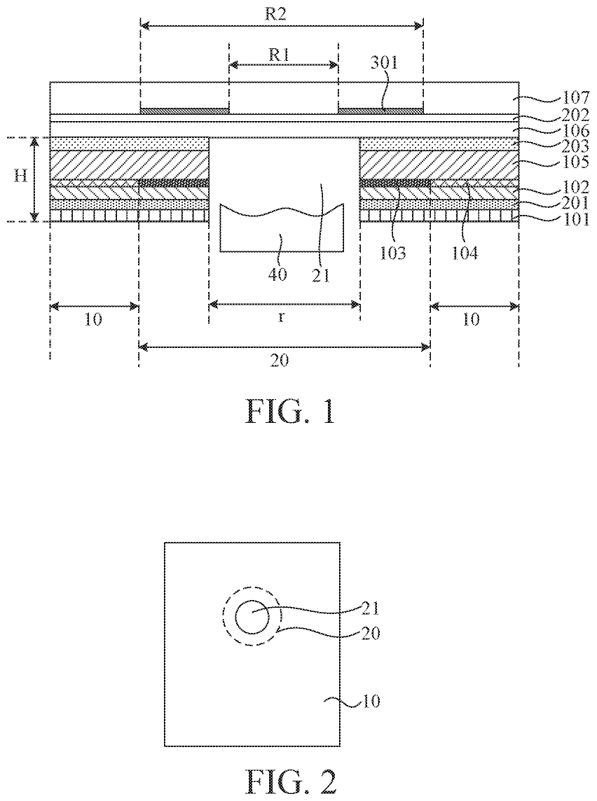

Shown in FIG. 1 is a structural schematic diagram of a film layer of a display device provided by an embodiment of the present application. The display device includes a display area 10 and an electronic component installation area 20 corresponding to an installation position of an electronic component. In the film layer structure, the display device includes a backplate 101, a display panel, a polarizing functional layer 105, a touch functional layer 106, and a cover plate 107.

The display panel is disposed on a side of the backplate 101. The polarizing functional layer 105 is disposed on a side of the display panel away from the backplate 101. The touch functional layer 106 is disposed on a side of the polarizing functional layer 105 away from the display panel, and the light transmittance of the touch functional layer 106 is greater than a threshold value. The cover plate 107 is disposed on a side of the touch functional layer 106 away from the polarizing functional layer 105, wherein an opening 21 is formed in the electronic component installation area 20 of the display device, and the opening 21 penetrates the backplate 101, the display panel, and the polarizing functional layer 105.

Shown in FIG. 2 is a schematic plan view of a display device provided by an embodiment of the present application. The display device includes a display area 10 and an electronic component installation area 20 corresponding to an installation position of an electronic component. In this application, the electronic component is a camera.

In the present application, the display panel is an organic light-emitting diode (OLED) display panel, and the display panel includes a stacked drive circuit layer 102 and a light-emitting functional layer.

The drive circuit layer 102 is bonded to a side of the backplate 101 by the pressure-sensitive adhesive layer 201 and includes a plurality of thin film transistors. Taking a top-gate thin film transistor as an example, the drive circuit layer 102 includes a substrate, a buffer layer, an active layer, a gate insulating layer, a gate layer, an interlayer insulating layer, a source-drain layer, and a planarization from bottom to top (not shown).

When the display device in the present application is a flexible panel, the substrate is a flexible substrate, such as polyimide, polycarbonate, polyethersulfone, polyethylene terephthalate, polyethylene naphthalate, polyaryl compounds or glass fiber reinforced plastics, etc. First, it is formed on a glass substrate by coating. After the manufacturing of the display device is completed, the glass substrate is peeled off. The method of peeling can be a laser peeling method.

A buffer layer is formed on a side of the substrate, and the material of the buffer layer can be an inorganic material such as silicon oxide and silicon nitride. The active layer is formed on the buffer layer, the material of the active layer is a metal oxide, such as indium gallium zinc oxide (IGZO), but not limited to this. It can also be one or more of aluminum zinc oxide (AZO), indium zinc oxide (IZO), zinc oxide (ZnO), indium oxide (In₂O₃), boron-doped zinc oxide (BZO), or magnesium-doped zinc oxide (MZO). In addition, the active layer can also be a polysilicon material or other materials.

A gate insulating layer is formed on the active layer. The material of the gate insulating layer can be inorganic materials such as silicon oxide or silicon nitride.

A gate layer is formed on the gate insulating layer. The material of the gate layer can be molybdenum, aluminum, copper, but not limited to this. It can also be chromium, tungsten, titanium, tantalum, and alloys containing them, and the material is not specifically limited here. The gate layer is patterned to form a gate by an etching process.

An interlayer dielectric layer is formed on the gate layer. The material of the interlayer dielectric layer can be an inorganic material such as silicon oxide or silicon nitride.

A source/drain layer is formed on the interlayer dielectric layer. The material of the source/drain layer can be molybdenum, aluminum, or copper, but is not limited to this. It can also be chromium, tungsten, titanium, tantalum, or alloys containing them. The source/drain electrodes are patterned by an etching process, and the source/drain electrodes are connected to the active layer through the first via-hole.

A planarization layer is formed on the source/drain layer. The material of the planarization layer can be a photoresist, which is formed on the source/drain layer by coating.

The description of the film layers in the above drive circuit layer 102 takes a top-gate thin film transistor as an example. Certainly, the structure of the drive circuit layer 102 is not limited thereto, and may also include a bottom-gate thin film transistor.

A light-emitting functional layer is directly formed on a side of the drive circuit layer 102 away from the backplate 101. The light-emitting functional layer includes a first electrode (not shown), a pixel definition layer 103, a light-emitting material layer 104, and a second electrode (not shown).

A first electrode is formed on the drive circuit layer 102 and is connected to the drain of the thin film transistor through a second via-hole penetrating the planarization layer. The first electrode includes a plurality of first drilling areas, the pixel definition layer 103 is formed in the first drilling area, and after forming the pixel definition layer 103, the first electrode is positioned in the drilling area of the pixel definition layer 103. Alight-emitting material layer 104 is formed on the first electrode, and the light-emitting material layer 104 is also positioned in the drilling area and includes a hole injection layer, a hole transport layer, a light-emitting layer, an electron transport layer, and an electron injection layer provided in a stack. Then, a second electrode is formed on the light-emitting functional layer. The second electrode extends to cover the light-emitting material layer 104 and extends to cover the pixel definition layer 103.

After the manufacturing of the light-emitting functional layer is completed, the polarizing functional layer 105 is bonded to the light-emitting surface. The arrangement of the polarizing functional layer 105 allows external light to be blocked to prevent the display device from external interference. The polarizing functional layer 105 can be a conventional polarizer or can be formed of a black photoresist material.

The touch functional layer 106 is disposed on a side of the polarizing functional layer 105 away from the light-emitting functional layer. In this embodiment, the touch functional layer 106 is an out-of-cell type touch control, which includes a plurality of touch electrodes. The touch functional layer 106 is first prepared and then bonded to the polarizing functional layer 105. That is, the touch functional layer 106 is disposed in both the display area 10 and the electronic component installation area 20. In the present application, the light transmittance of the touch functional layer 106 is greater than a threshold value, the light transmittance effect of the electronic component installation area 20 can be ensured, so that the electronic component can work normally.

The cover plate 107 is a transparent material and is attached to the touch functional layer 106.

In the electronic component installation area 20, an opening 21 is formed in the display device, the opening 21 penetrates through the backplate 101, the display panel, and the polarizing functional layer 105 to form an accommodating space. A supporting member 40 is provided in the opening 21 for carrying electronic components. The size of the opening 21 does not exceed the electronic component installation area 20.

When forming the opening 21, the ultraviolet picosecond laser is used to cut the backplate 101 from below to form a through-hole, which can not only minimize the thermal influence of the heat-affected zone (HAZ) but also reduces the cutting range. The depth of field H is controlled by controlling the energy of the ultraviolet picosecond laser. The cutting process is stopped under the touch functional layer 106, the touch functional layer 106 and the cover plate 1078 are not cut, and ensures that the touch functional layer 106 is not affected by the laser and fails to work.

In the prior art, the touch layer adopts DOT technology. After the opening is formed in the electronic component installation area, a through-hole wiring bypass process needs to be performed, the manufacturing process is relatively complicated, and the technical threshold is high.

In the embodiment of the present application, the light transmittance of the touch functional layer 106 is greater than the threshold value so that the light transmittance of the electronic component can be ensured. The touch functional layer 106 can be provided in a whole layer and does not need to be drilled. When forming the opening 21, it only needs to be cut to the film layer below the touch functional layer 106, and the touch functional layer 106 itself does not need to be cut, so the cutting depth is reduced. This design can achieve the purpose of touch control and placing electronic components, and the wiring bypass process that is required in the prior art is omitted after the touch functional layer 106 is cut. The manufacturing process is simple and the cost is reduced.

In one embodiment, a material of the touch functional layer includes silver nanowires (AgNW), and light transmittance of the silver nanowires is as high as 92%, so that the light transmittance of the electronic component installation area 21 can be ensured.

In one embodiment, the touch functional layer 106 is bonded to the cover plate 107 through a first adhesive layer 202 and bonded to the polarizing functional layer 105 through a second adhesive layer 203, and the opening 21 penetrates the second adhesive layer 203.

The first adhesive layer 202 and the second adhesive layer 203 are optical adhesives. Since the optical adhesive is also a transparent film layer, it will not affect the light transmittance. When the opening 21 is formed by cutting, the opening 21 penetrates the second adhesive layer 203.

In the electronic component installation area 20, a light-shielding layer 301 is further disposed between the cover plate 107 and the polarizing functional layer 105. The light-shielding layer 301 is a ring structure concentric with the opening 21.

In one embodiment, a material of the light-shielding layer 301 is ink. The ink is opaque and can be used to absorb excess light entering the camera. The excess light includes ambient light incident through the cover plate 107, and can also include light emitted by the light-emitting functional layer and reflected by the polarizing functional layer 105. By providing the light-shielding layer 301, excess light can be absorbed to prevent light leakage from affecting photo shooting quality. Certainly, the light-shielding layer 301 can also be other opaque material.

In one embodiment, an inner diameter R1 of the light-shielding layer 301 is smaller than or equal to an inner diameter r of the opening 21. Since the supporting member 40 is provided in the opening 21, the camera is fixed on the supporting member 40, and the size of the camera is smaller than the opening 21, the inner diameter R1 of the light-shielding layer 301 is less than or equal to the inner diameter r of the opening 21. Under the premise of not affecting the normal working of the camera, light leakage is alleviated as much as possible. Since the display area 10 needs to display images, the light-shielding layer 301 is only provided in the electronic component installation area 21, and an outer diameter R2 of the light-shielding layer 301 is less than or equal to the area of the electronic component installation area 21.

In one embodiment, the light-shielding layer 301 is formed in at least one position between the cover plate 107 and the touch functional layer 106 or the touch functional layer 106 and the polarizing functional layer 105. That is, the light-shielding layer 301 can be provided only between the cover plate 107 and the touch functional layer 106, or only between the touch functional layer 106 and the polarizing functional layer 105, or the light-shielding layer 301 can be provided between the cover plate 107 and the touch functional layer 106, and also between the touch functional layer 106 and the polarizing functional layer 105. Since the cover plate 107 and the touch functional layer 106 are bonded by the first adhesive layer 202, and the touch functional layer 106 and the polarizing functional layer 105 are bonded by the second adhesive layer 203, the light-shielding layer 301 can be provided on both the upper and lower sides of the first adhesive layer 202 and the upper and lower sides of the second adhesive layer 203. Those skilled in the art can set the position of the light-shielding layer 301 according to their needs. In a case that the light-shielding layer 301 is disposed between the touch functional layer 106 and the polarizing functional layer 105, the cutting process is stopped at the light-shielding layer 301 when forming the opening 21.

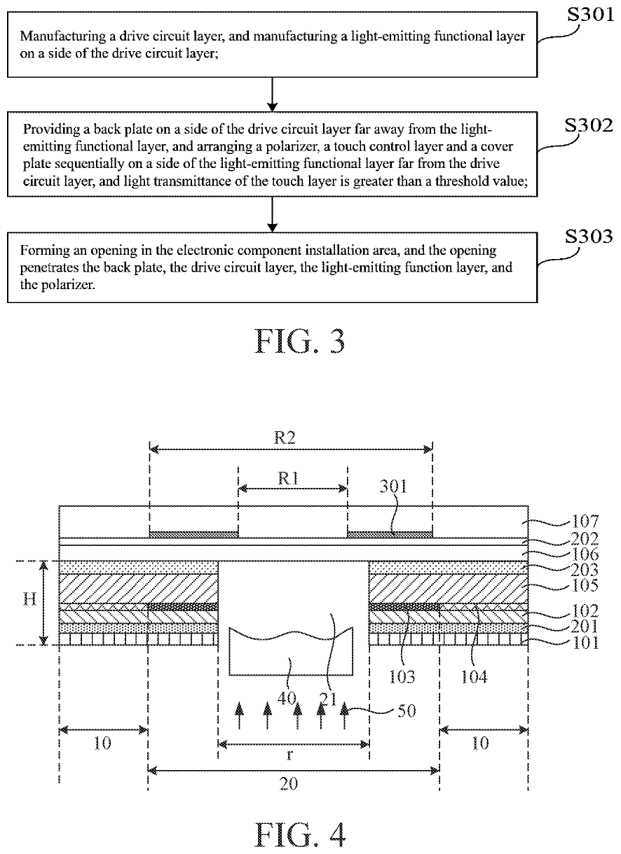

As shown in FIG. 3, the present application also provides a manufacturing method of a display device. Specific steps include:

S301, providing a backplate, a display panel, a polarizing functional layer, a touch functional layer, and a cover plate, wherein light transmittance of the touch functional layer is greater than a threshold value;

S302, bonding the backplate, the display panel, the polarizing functional layer, the touch functional layer, and the cover plate together; and

S303, forming an opening in the electronic component installation area, and allowing the opening to penetrate the backplate, the display panel, and the polarizing functional layer.

In step S301, a backplate, a display panel, a polarizing functional layer, a touch functional layer, and a cover plate are provided, and the light transmittance of the touch functional layer is greater than a threshold value. In the present application, the display panel is the OLED display panel, and the display panel includes a stacked drive circuit layer 102 and a light-emitting functional layer.

The drive circuit layer 102 includes a plurality of thin film transistors. Taking a top-gate thin film transistor as an example, the drive circuit layer 102 includes a substrate, a buffer layer, an active layer, a gate insulating layer, a gate layer, an interlayer insulating layer, a source-drain layer, and a planarization layer from bottom to top (not shown). A description of the structure of each film layer in the above drive circuit layer 102 takes a top-gate thin film transistor as an example. Certainly, the structure of the drive circuit layer 102 is not limited thereto, and may also include a bottom-gate thin film transistor.

The light-emitting functional layer is directly formed on a side of the drive circuit layer 102 away from the backplate 101. The light-emitting functional layer includes a first electrode (not shown), a pixel definition layer 103, a light-emitting material layer 104, and a second electrode (not shown).

The first electrode is formed on the drive circuit layer 102, and is connected to the drain of the thin film transistor through a second via-hole penetrating the planarization layer. The first electrode includes a plurality of first opening areas, and the pixel definition layer 103 is formed in the first opening areas. After the pixel definition layer 103 is formed, the first electrode is positioned in the opening area of the pixel definition layer 103. A light-emitting material layer 104 is formed on the first electrode, and the light-emitting material layer 104 is also positioned in the opening area, including a hole injection layer, a hole transport layer, a light-emitting layer, an electron transport layer, and an electron injection layer provided in a stack. Then, a second electrode is formed on the light-emitting functional layer. The second electrode extends to cover the light-emitting material layer 104 and extends to cover the pixel definition layer 103.

The polarizing functional layer 105 can be a conventional polarizer, or can be made of a black photoresist material. The cover plate 107 is a transparent material.

The touch functional layer 106 includes a plurality of touch electrodes, and the light transmittance of the touch functional layer 106 is greater than the threshold value. In one embodiment, the material of the touch functional layer is silver nanowire AgNW, and the light transmittance of the silver nanowire is as high as 92%. Therefore, the light transmittance of the electronic component installation area 21 can be achieved.

In step S302, the backplate, the display panel, the polarizing functional layer, the touch functional layer and the cover plate are bonded together.

In one embodiment, when bonding the components, the polarizing functional layer 105 is first bonded to the display panel. Then, the touch functional layer 106 is bonded to the polarizing functional layer 105, and then, a cover plate 107 is bonded to the touch functional layer 106, and the backplate 101 is bonded under the display panel.

In one embodiment, when bonding the components, the polarizing functional layer 105 is first bonded to the display panel, and the backplate 101 is bonded under the display panel. Then, the touch functional layer 106 and the cover plate 107 are bonded together, and finally the polarizing functional layer 105 and the touch functional layer 106 are bonded together.

The polarizing functional layer 105 is bonded to the light-exiting surface of the display panel, so that external light is blocked, and the display device is prevented from external interference.

The touch functional layer 106 is disposed on a side of the polarizing functional layer 105 away from the light-emitting functional layer. After the touch functional layer 106 is bonded, an entire layer thereof is provided. That is, the touch functional layer 106 is provided in both the display area 10 and the electronic component installation area 20. In the present application, the light transmittance of the touch functional layer 106 is greater than a threshold value, so the light transmittance effect of the electronic component installation area 20 can be ensured, such that the electronic component can work normally.

The touch functional layer 106 is bonded to the cover plate 107 through the first adhesive layer 202, and bonded to the polarizing functional layer 105 through the second adhesive layer 203. The first adhesive layer 202 and the second adhesive layer 203 are optical adhesives. Since the optical adhesive is also a transparent film layer, it will not affect the light transmittance.

The cover plate 107 is bonded to the touch functional layer 106. The backplate 101 is bonded to a side of the display panel away from the polarizing functional layer 105, and they are connected through a pressure-sensitive adhesive layer 201.

In one embodiment, a light-shielding layer 301 is further disposed between the cover plate 107 and the polarizing functional layer 105 in the electronic component installation area 20. The light-shielding layer 301 is a ring structure concentric with the opening 21. The light-shielding layer 301 is formed by coating or inkjet printing.

In one embodiment, the material of the light-shielding layer 301 is ink. The ink is opaque material, which can be used to absorb excess light entering the camera. The excess light includes ambient light incident through from the cover plate 107, and may also include light emitted by the light-emitting functional layer and reflected by the polarizing functional layer 105. By providing the light-shielding layer 301, the excess light can be absorbed to avoid light leakage from affecting photo shooting quality. Certainly, the light-shielding layer 301 may also be other opaque materials.

In one embodiment, the inner diameter R1 of the light-shielding layer 301 is smaller than or equal to the inner diameter r of the opening 21. Since the supporting member 40 is provided in the opening 21, the camera is fixed on the supporting member 40, and the size of the camera is smaller than the opening 21, the inner diameter R1 of the light-shielding layer 301 is less than or equal to the inner diameter r of the opening 21. Under the premise of not affecting the normal working of the camera, light leakage is alleviated as much as possible.

In one embodiment, the light-shielding layer 301 is formed in at least one position between the cover plate 107 and the touch functional layer 106 or between the touch functional layer 106 and the polarizing functional layer 105.

In step S303, an opening is formed in the electronic component installation area, and allowing the opening penetrates the backplate, the display panel, and the polarizing functional layer.

As shown in FIG. 4, an ultraviolet picosecond laser 50 is used to cut the backplate 101, the display panel, and the polarizing functional layer 105 to form the opening 21 on a side of the backplate 101 away from the display panel. The supporting member 40 is provided in the opening 21 for carrying electronic components.

When the opening 21 is formed, the ultraviolet picosecond laser is used to cut the backplate 101 from the below side thereof to form a through-hole, which can not only minimize the thermal influence of the heat-affected zone (HAZ) but also reduce the cutting range. The depth of field H is controlled by controlling the energy of the ultraviolet picosecond laser. The cutting process is stopped under the touch functional layer 106. The touch functional layer 106 and the cover plate 107 would not be cut. It can ensure that the touch functional layer 106 is not affected by the laser and fails to work.

In this embodiment, the touch functional layer 106 is an out-of-cell type touch control. The touch functional layer 106 is bonded to the cover plate 107 through the first adhesive layer 202 and bonded to the polarizing functional layer 105 through the second adhesive layer 203. When the opening 21 is formed by cutting, the opening 21 penetrates the second adhesive 203.

In the prior art, the touch layer adopts DOT technology. After an opening is formed in the electronic component installation area, the through-hole bypass process needs to be performed in the drilling area, the manufacturing process is relatively complicated, and the technical threshold is high.

In the manufacturing method of the embodiment of the present application, the light transmittance of the touch functional layer 106 is greater than a threshold value so that the light transmittance of the electronic component can be ensured. The touch functional layer 106 can be provided in a whole layer and does not need to be drilled. When forming the opening 21, the opening 21 only needs to be cut to the film layer below the touch functional layer 106, and the touch functional layer 106 itself does not need to be cut, so the cutting depth is reduced. This design can achieve the purpose of touch control and placing electronic components, and the wiring bypass process that is required in the prior art is omitted after the touch functional layer 106 is cut. The manufacturing process is simple and the cost is reduced.

The present application also provides a terminal device, including a display device and housing. The display device is the display device according to any one of the foregoing embodiments.

According to the above embodiments, it is known that: The present application provides a display device, a manufacturing method thereof, and a terminal device. The display device includes a display area and an electronic component installation area corresponding to an installation position of an electronic component. The display device includes a backplate, a display panel, a polarizing functional layer, a touch functional layer, and a cover plate. The display panel is disposed on a side of the backplate. The polarizing functional layer is disposed on a side of the display panel away from the backplate. The touch functional layer is disposed on a side of the polarizing functional layer away from the display panel, wherein light transmittance of the touch functional layer is greater than a threshold value. The cover plate is disposed on a side of the touch functional layer away from the polarizing functional layer, wherein a hole is formed in the electronic component installation area of the display device, and the hole penetrates the backplate, the display panel, and the polarizing functional layer. The light transmittance of the touch functional layer of the present application is greater than a threshold value, so the light transmittance of electronic components can be ensured. The hole in the electronic component installation area does not need to penetrate the touch functional layer, and can also achieve the purpose of touch control and placing electronic components. Therefore, no wiring bypass process is needed in the touch functional layer, the manufacturing process is simple, and the cost is reduced.

As described above, although the present application has disclosed the preferred embodiments, they are not intended to limit this application. Those of ordinary skill in the art can make various changes or modifications without departing from the spirit and scope of this application. Therefore, the protection scope of the present application is subject to the scope defined by the claims.

What is claimed is:

1. A display device, comprising a display area and an electronic component installation area corresponding to an installation position of an electronic component, wherein the display device comprises:
a backplate;
a display panel disposed on a side of the backplate;
a polarizing functional layer disposed on a side of the display panel away from the backplate;
a touch functional layer disposed on a side of the polarizing functional layer away from the display panel, wherein a light transmittance of the touch functional layer is greater than a threshold value; and
a cover plate disposed on a side of the touch functional layer away from the polarizing functional layer;
wherein an opening is formed in the electronic component installation area of the display device, and the opening penetrates the backplate, the display panel, and the polarizing functional layer.

2. The display device according to claim 1, wherein a material of the touch functional layer comprises silver nanowires.

3. The display device according to claim 1, wherein the touch functional layer is bonded to the cover plate through a first adhesive layer and bonded to the polarizing functional layer through a second adhesive layer, and the opening penetrates the second adhesive layer.

4. The display device according to claim 3, wherein the first adhesive layer and the second adhesive layer are made of optical adhesives.

5. The display device according to claim 1, wherein a light-shielding layer is further disposed between the cover plate and the polarizing functional layer in the electronic component installation area, and the light-shielding layer is a ring structure concentric with the opening.

6. The display device according to claim 5, wherein an inner diameter of the light-shielding layer is less than or equal to an inner diameter of the opening.

7. The display device according to claim 5, wherein the light-shielding layer is formed in at least one position between the cover plate and the touch functional layer, or between the touch functional layer and the polarizing functional layer.

8. The display device according to claim 5, wherein a material of the light-shielding layer is an ink.

9. A manufacturing method of a display device, wherein the display device comprising a display area and an electronic component installation area corresponding to an installation position of an electronic component, and the manufacturing method comprises steps of:
providing a backplate, a display panel, a polarizing functional layer, a touch functional layer, and a cover plate, wherein a light transmittance of the touch functional layer is greater than a threshold value;
bonding the backplate, the display panel, the polarizing functional layer, the touch functional layer, and the cover plate together; and
forming an opening in the electronic component installation area, and allowing the opening to penetrate the backplate, the display panel, and the polarizing functional layer.

10. The method of manufacturing the display device according to claim 9, wherein the step of forming the opening in the electronic component installation area, and allowing the opening to penetrate the backplate, the display panel, and the polarizing functional layer comprises:
using an ultraviolet picosecond laser on a side of the backplate away from the display panel to cut the backplate, the display panel, and the polarizing functional layer to form the opening.

11. The method of manufacturing the display device according to claim 9, wherein the step of providing the backplate, the display panel, the polarizing functional layer, the touch functional layer, and the cover plate, wherein the light transmittance of the touch functional layer is greater than a threshold value comprises: providing a touch functional layer comprising a material made of silver nanowires.

12. The method of manufacturing the display device according to claim 9, wherein the step of bonding the backplate, the display panel, the polarizing functional layer, the touch functional layer, and the cover plate together comprises steps of:
bonding the touch functional layer to the cover plate through a first adhesive layer, and bonding the touch functional layer to the polarizing functional layer through a second adhesive layer.

13. The method of manufacturing the display device according to claim 12, wherein the steps of bonding the touch functional layer to the cover plate through the first adhesive layer, and bonding the touch functional layer to the polarizing functional layer through the second adhesive layer comprises:
bonding the touch functional layer to the cover plate through the first adhesive layer made of an optical adhesive and bonding the touch functional layer to the polarizing functional layer through the second adhesive layer made of the optical adhesive.

14. The method of manufacturing the display device according to claim 9, wherein a further step before the step of forming the opening in the electronic component installation area comprises:
providing a light-shielding layer between the cover plate and the polarizing functional layer in the electronic component installation area, and the light-shielding layer being a ring structure concentric with the opening.

15. The method of manufacturing the display device according to claim 14, wherein the further step of providing the light-shielding layer between the cover plate and the polarizing functional layer in the electronic component installation area, and the light-shielding layer being the ring structure concentric with the opening comprises:
providing the light-shielding layer, wherein an inner diameter of the light-shielding layer is less than or equal to an inner diameter of the opening.

16. The method of manufacturing the display device according to claim 14, wherein the further step of providing the light-shielding layer between the cover plate and the polarizing functional layer in the electronic component installation area comprises:
forming the light-shielding layer in at least one position between the cover plate and the touch functional layer or the touch functional layer and the polarizing functional layer.

17. The method of manufacturing the display device according to claim 14, wherein the further step of providing the light-shielding layer between the cover plate and the polarizing functional layer in the electronic component installation area comprises:
forming the light-shielding layer using a material made of an ink.

18. A terminal device, comprising a display device and a housing, wherein the display device comprises a display area and an electronic component installation area corresponding to an installation position of an electronic component, and the display device comprises:
a backplate;
a display panel disposed on a side of the backplate;
a polarizing functional layer disposed on a side of the display panel away from the backplate;
a touch functional layer disposed on a side of the polarizing functional layer away from the display panel, and a light transmittance of the touch functional layer is greater than a threshold value; and
a cover plate disposed on a side of the touch functional layer away from the polarizing functional layer;
wherein an opening is formed in the electronic component installation area of the display device, and the opening penetrates the backplate, the display panel, and the polarizing functional layer.

19. The terminal device according to claim 18, wherein a material of the touch functional layer comprises silver nanowires.

20. The terminal device according to claim 18, wherein the touch functional layer is bonded to the cover plate through a first adhesive layer and bonded to the polarizing functional layer through a second adhesive layer, and the opening penetrates the second adhesive layer.
